(19) United States
(12) Patent Application Publication
(10) Pub. No.: US 2026/0164545 A1
(43) Pub. Date: Jun. 11, 2026

(54) CIRCUIT BOARD

(71) Applicant: CANON KABUSHIKI KAISHA, Tokyo (JP)

(72) Inventor: SHOJI MATSUMOTO, Kanagawa (JP)

(21) Appl. No.: 19/408,135

(22) Filed: Dec. 3, 2025

(30) Foreign Application Priority Data
Dec. 6, 2024 (JP) 2024-213119

(51) Int. Cl. H05K 1/02

(52) U.S. Cl. CPC H05K 1/0296; H05K 2201/10015; H05K 2201/10022; H05K 2201/10151; H05K 2201/10621

(57) ABSTRACT

A circuit board includes a wiring board; a connector that is mounted on the wiring board and has a main terminal and a sub-terminal; a power supply circuit that has an input terminal and an output terminal; a signal circuit that has a first terminal and a second terminal; and a signal transmitting and receiving circuit that has a power supply terminal and a signal terminal. The wiring board includes a first wiring that connects the main terminal and the input terminal; a second wiring that connects the input terminal and the first terminal without passing through the main terminal; a third wiring that connects the output terminal and the power supply terminal; and a fourth wiring that connects the second terminal and the signal terminal. The second wiring passes between the main terminal and the sub-terminal.

### BACKGROUND

### Field of the Technology

The present disclosure relates to a circuit board.

### Description of Related Art

Data communication using digital signals is performed between two semiconductor devices mounted in an electronic equipment. The digital signal is transmitted through wiring or a cable mounted on the circuit board. The circuit board and the cable are connected to each other via a connector. In recent years, to simplify the system of the electronic equipment, a system has been adopted in which a signal transmitted and received by a semiconductor element and a DC power source for driving the semiconductor element are superimposed on a single cable and transmitted. For example, Japanese Patent Laid-Open No. 2022-34594 discloses a technique in which a signal and a power source transmitted through a single coaxial cable are separated by a signal-power source separation circuit mounted on a circuit board and supplied to a signal terminal and a power source terminal of a semiconductor element, respectively.

However, there is a possibility of signal degradation between the signal terminal of the semiconductor device and the signal terminal of the coaxial connector.

### SUMMARY

According to one aspect of the present disclosure, there is provided a circuit board including: a wiring board; a connector that is mounted on the wiring board and has a main terminal and a sub-terminal; a power supply circuit that is mounted on the wiring board and has an input terminal and an output terminal; a signal circuit that is mounted on the wiring board and has a first terminal and a second terminal; and a signal transmitting and receiving circuit that is mounted on the wiring board and has a power supply terminal and a signal terminal, wherein the main terminal and the sub-terminal pass through the wiring board, wherein the wiring board includes: a first wiring that connects the main terminal and the input terminal; a second wiring that connects the input terminal and the first terminal without passing through the main terminal; a third wiring that connects the output terminal and the power supply terminal; and a fourth wiring that connects the second terminal and the signal terminal, and wherein the second wiring passes between the main terminal and the sub-terminal.

Features of the present disclosure will become apparent from the following description of embodiments with reference to the attached drawings. The following description of embodiments is described by way of example.

### BRIEF DESCRIPTION OF THE DRAWINGS

FIG. 1A is a top view illustrating a circuit board according to a first embodiment.

FIG. 1B is a cross-sectional view of the circuit board illustrated in FIG. 1A taken along line A-A'.

FIG. 1C is a top view illustrating Example 2 of the circuit board according to the first embodiment.

FIG. 1D is a top view illustrating Example 3 of the circuit board according to the first embodiment.

FIG. 1E is a top view illustrating Example 4 of the circuit board according to the first embodiment.

FIG. 1F is a top view illustrating Example 5 of the circuit board according to the first embodiment.

FIG. 2 is a top view illustrating Comparative Example of the circuit board according to the first embodiment.

FIG. 3A is a diagram illustrating simulation results of reflection characteristics in Example 1 and Comparative Example of the circuit board according to the first embodiment.

FIG. 3B is a diagram illustrating reflection characteristics in Examples 2 to 5 of the circuit board according to the first embodiment.

FIG. 4 is a top view illustrating a circuit board according to a second embodiment.

FIG. 5 is a diagram illustrating simulation results of reflection characteristics in Example and Comparative Example of the circuit board according to the second embodiment.

### DESCRIPTION OF THE EMBODIMENTS

Hereinafter, embodiments of the present disclosure will be described in detail with reference to the drawings. It should be noted that the present disclosure is not limited to the following embodiments and can be appropriately changed without departing from the gist of the present disclosure. In the drawings described below, components with the same functions are denoted by the same reference numerals, and descriptions thereof may be omitted or simplified.

### First Embodiment

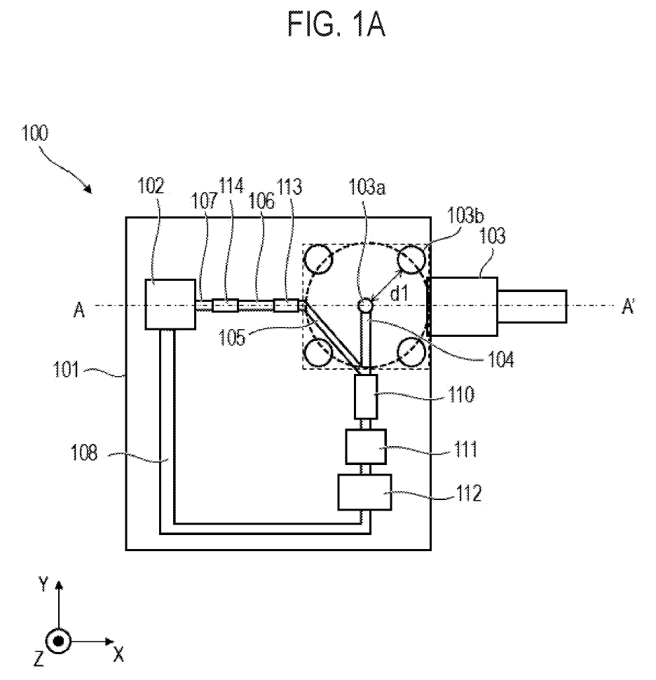

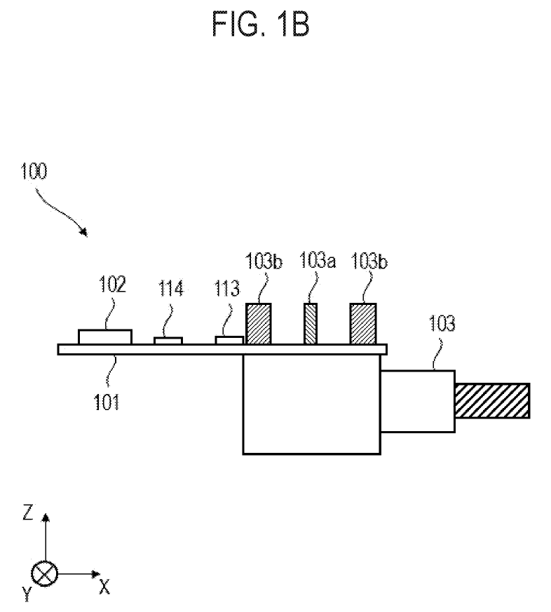

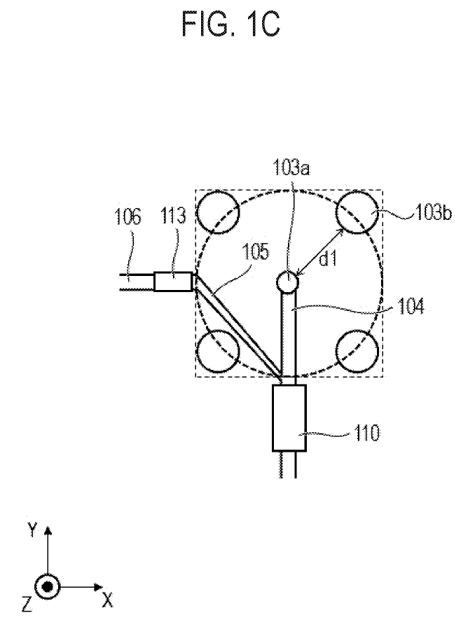

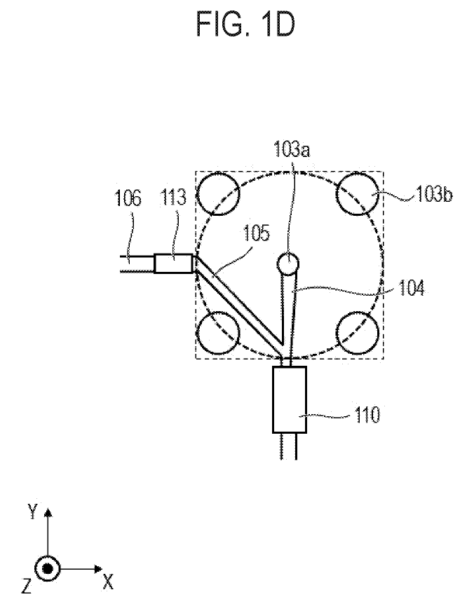

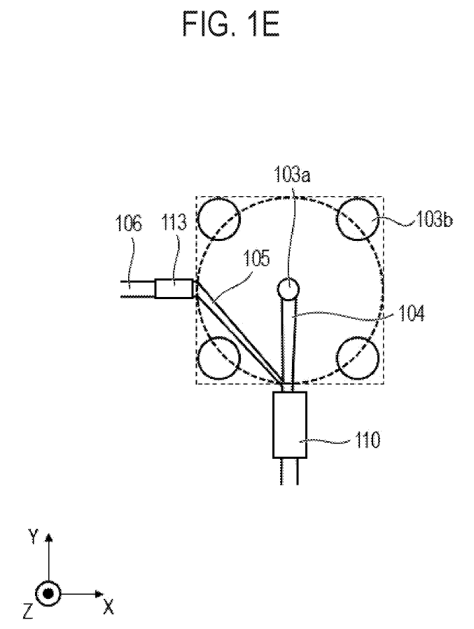

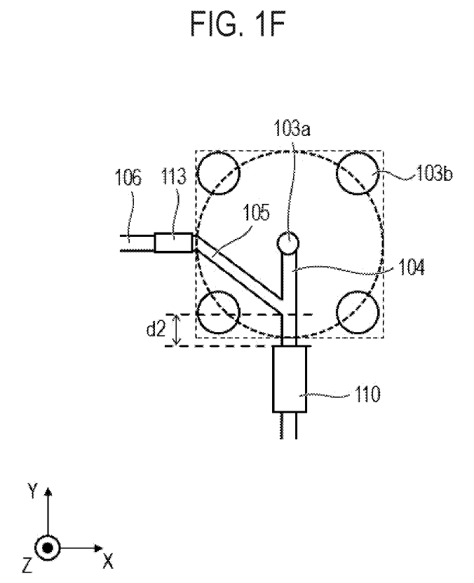

FIG. 1A is a top view illustrating a circuit board 100 according to the present embodiment. FIG. 1B is a cross-sectional view taken along line A-A' of the circuit board 100 illustrated in FIG. 1A. FIGS. 1C, 1D, 1E and 1F are top views illustrating examples of the circuit board 100 illustrated in FIG. 1A.

The circuit board 100, for example, is a printed circuit board. The circuit board 100 includes a printed wiring board 101, a signal transmitting and receiving circuit 102, a coaxial connector 103, a first signal filter (power supply circuit) 110, a second signal filter (power supply circuit) 111, a DC-DC converter (power supply circuit) 112, a capacitor (signal circuit) 113, and a resistor (signal circuit) 114. The signal transmitting and receiving circuit 102 is a semiconductor element. The signal transmitting and receiving circuit 102 has a signal terminal (not illustrated) for transmitting and receiving signals and a terminal (not illustrated) to which power is supplied from the outside. The coaxial connector 103 includes a signal terminal 103a (main terminal), a ground terminal 103b (sub-terminal), and a main body portion (not illustrated). The main body portion of the coaxial connector 103 is a connectable portion to which a coaxial cable is connected. In the present embodiment, the coaxial connector 103 has four ground terminals 103b. The signal terminal 103a is surrounded by four ground terminals 103b on the same surface.

The first signal filter 110 and the second signal filter 111 are, for example, coils or ferrite beads. The signal transmitting and receiving circuit 102, the capacitor 113, the resistor 114, the first signal filter 110, the second signal filter 111, and the DC-DC converter 112 are mounted on one main surface (hereinafter, this is referred to as a "first mounting surface") of the printed wiring board 101. The main body portion (connection portion with the coaxial cable) of the coaxial connector 103 is disposed on the second mounting surface opposite to the first mounting surface on which the signal transmitting and receiving circuit 102 is mounted. As illustrated in FIG. 1B, the signal terminal 103a and the ground terminal 103b penetrate the printed wiring board 101 from the second mounting surface toward the first mounting surface and protrude in the Z direction from the first mounting surface. That is, the coaxial connector 103 is inserted and mounted from the second mounting surface. The signal terminal 103a and the ground terminal 103b may be soldered to the first mounting surface.

Next, the connection structure of circuits will be described. The signal terminal 103a of the coaxial connector 103 is connected to one end (input terminal of the signal circuit) of the first signal filter 110 via a wiring (first wiring) 104 on the first mounting surface. One end of the first signal filter 110 is connected to one end (first terminal of the signal circuit) of the capacitor 113 via a wiring (second wiring) 105 provided on the first mounting surface. The wiring 105 passes between the signal terminal 103a of the coaxial connector 103 and one ground terminal 103b of the four ground terminals 103b in a plan view (X-Y plane in the drawing) of the printed wiring board 101. The length of the wiring 104 is shorter than that of the wiring 105. The wiring 105 does not pass between the remaining three ground terminals 103b (other sub-terminals) and the signal terminal 103a.

The other end of the first signal filter 110 is connected to one end of the second signal filter 111. The other end of the second signal filter 111 is connected to one end of the DC-DC converter 112. The other end (output terminal of the power supply circuit) of the DC-DC converter 112 is connected to a power supply terminal of the signal transmitting and receiving circuit 102 via a wiring 108 (third wiring). The ground terminal 103b of the coaxial connector 103 is connected to a ground (not illustrated) of the printed wiring board 101. The other end of the capacitor 113 is connected to one end of the resistor 114 via the wiring 106. The other end (second terminal of the signal circuit) of the resistor 114 is connected to the signal terminal of the signal transmitting and receiving circuit 102 via the wiring 107 (fourth wiring). The terminal of the capacitor 113 and a terminal of the resistor 114 are soldered to the first mounting surface. Since the resistor 114 is disposed in the vicinity of one end (signal terminal) of the signal transmitting and receiving circuit 102, the sum of the input impedance of the signal transmitting and receiving circuit 102 and the resistance value of the resistor 114 matches the characteristic impedance of the wiring 106.

In the present embodiment, in consideration of the sizes of the first signal filter 110, the first signal filter 110 is disposed outside the region surrounded by the plurality of ground terminals 103b of the coaxial connector 103. That is, in a plan view of the printed wiring board 101, a distance between the signal terminal 103a and one end of the first signal filter 110 is longer than a distance d1 between the signal terminal 103a and the ground terminal 103b. Such an arrangement structure is suitable when the size of the first signal filter 110 is large and the first signal filter 110 cannot be disposed in a region surrounded by the ground terminal 103b. Note that, also in the case of preventing short-circuiting between the first signal filter 110 and the ground terminal 103b due to mounting failure, the first signal filter 110 may be disposed outside the region surrounded by the plurality of ground terminals 103b.

Next, the operation of circuits will be described. When a coaxial cable (not illustrated) is connected to the connectable portion of the coaxial connector 103, a signal and DC power are transmitted to the circuit board 100 from an external device (not illustrated) via the coaxial cable. The signal and the DC power that have reached the coaxial connector 103 are transmitted to the wiring 104 provided on the first mounting surface via the signal terminal 103a. The signal transmitted to the wiring 104 and the DC power are separated by the first signal filter 110, the second signal filter 111, and the capacitor 113.

The first signal filter 110 is connected to the wiring 104 and has a first cutoff frequency. The second signal filter 111 is connected to the first signal filter 110 and has a second cutoff frequency lower than the first cutoff frequency. The DC-DC converter 112 is connected to the second signal filter 111, and outputs a power supply voltage to the power supply terminal of the signal transmitting and receiving circuit 102.

Since the first signal filter 110 has a low-pass filter characteristic, the high-frequency signal is transmitted to the wiring 105 without passing through the first signal filter 110 and reaches the capacitor 113. The capacitor 113 is short-circuited state with respect to the high-frequency signal. Therefore, the high-frequency signal reaches the signal terminal of the signal transmitting and receiving circuit 102 from the capacitor 113 via the wiring 106, the resistor 114, and the wiring 107. Here, the sum of the input impedance of the signal transmitting and receiving circuit 102 and the resistance value of the resistor 114 matches the characteristic impedance of the wiring 106. Therefore, reflection of the high-frequency signal does not occur.

The signal outputted from the signal terminal of the signal transmitting and receiving circuit 102 reaches one end of the first signal filter 110 via the wiring 107, the resistor 114, the wiring 106, the capacitor 113, and the wiring 105. Since the first signal filter 110 has a low-pass filter characteristic, the high-frequency signal is transmitted to the wiring 104 without passing through the first signal filter 110 and is transmitted to the signal terminal 103a of the coaxial connector 103. The signal that reaches the coaxial connector 103 is transmitted to the external device via the coaxial cable.

Since the first signal filter 110 has a high impedance with respect to a high-frequency signal, wiring and components connected to the other end of the first signal filter 110 do not become stubs. Therefore, the signals outputted from the signal transmitting and receiving circuit 102 and the received signals are not affected by reflection.

The second signal filter 111 operates when the frequency band of the signal outputted from the signal transmitting and receiving circuit 102 is different from the frequency band of the signal input to the signal transmitting and receiving circuit 102. With a single signal filter, there is a possibility that it cannot maintain a high impedance when frequency bands differ between transmission and reception. To shorten the stub, the first signal filter 110, located close to the signal terminal 103a, operates on the high-frequency signal. The second signal filter 111 operates on the low-frequency signal. At this time, the low-frequency signal may pass through the first signal filter 110. That is, the impedance of the first signal filter 110 is higher than that of the second signal filter 111 with respect to the high-frequency signal. On the other hand, the impedance of the second signal filter 111 is higher than that of the first signal filter 110 with respect to the low-frequency signal.

The DC power transmitted to the wiring 104 passes through the first signal filter 110 and the second signal filter 111, which are low-pass filters, and reaches the DC-DC converter 112. In addition, since the wiring 105 is connected to the capacitor 113, it is insulated from the DC power. That is, the DC power is not transmitted to the wiring 105 and does not reach the signal terminal of the signal transmitting and receiving circuit 102. The DC power passes through the first signal filter 110 and the second signal filter 111 and reaches the DC-DC converter 112. The DC power is converted into a power supply voltage required in the signal transmitting and receiving circuit 102 by the DC-DC converter 112 and reaches the power supply terminal of the signal transmitting and receiving circuit 102 through the wiring 108.

To suppress the loss of high-frequency signals in electronic equipment, it is effective to connect the signal terminal of a semiconductor element and the signal terminal of a coaxial connector at the shortest distance. However, a space for mounting the signal-power source separation circuit on the shortest straight line connecting the signal terminal of the semiconductor element and the signal terminal of the coaxial connector may be insufficient. In such a case, the signal-power source separation circuit needs to be disposed at a position deviated from a straight line connecting the signal terminal of the semiconductor element and the signal terminal of the coaxial connector. As a result, the wiring connecting the main signal wiring of the high-frequency signal and the signal-power source separation circuit becomes long, and the wiring becomes a stub, whereby the signal is reflected. In contrast, according to the circuit board 100 of the present embodiment, since there is no stub that reflects a high-frequency signal, signal degradation can be reduced.

Next, Examples 1 to 5 of the circuit board 100 illustrated in FIGS. 1A and 1B will be described. Examples 2 to 5 are modifications of Example 1.

### Example 1

Example 1 of the circuit board 100 illustrated in FIG. 1A will be described. The printed wiring board 101, according to Example 1, is a laminated substrate including six layers. The thicknesses of the first to sixth layers of the conductor layer in the printed wiring board 101 are 0.031 mm, 0.031 mm, 0.034 mm, 0.034 mm, 0.031 mm, and 0.031 mm, respectively. The material of the conductor layer is copper. An insulating layer is provided between adjacent conductor layers. The thickness of each insulating layer is 0.08mm between the first and second layers, 0.08 mm between the second and third layers, 0.964 mm between the third and fourth layers, 0.08 mm between the fourth and fifth layers, and 0.08 mm between the fifth and sixth layers. The dielectric constant is 4.3, and the dielectric loss tangent is 0.02. The material of the insulating layer is a glass epoxy resin. A solder resist is applied to both the first and sixth layers. The thickness of the solder resist in both the first layer and the sixth layer is 0.03 mm. The dielectric constant is 3.0, and the dielectric loss tangent is 0.02. The total thickness of the printed wiring board 101 is 1.536 mm.

The coaxial connector 103 has four ground terminals 103b. The four ground terminals 103b are disposed at four corners of the square shape. The arrangement pitch of the ground terminals 103b is 5.08 mm. The signal terminal 103a is disposed at an intersection of diagonal lines of the four ground terminals 103b. The distance d1 between the signal terminal 103a and the ground terminal 103b is 2.54 mm. The characteristic impedance of the coaxial connector 103 is 75 Ω. The length of the wiring 104 is 3.5 mm. The length of the wiring 105 is 4.6 mm. The length of the wiring 106 is 3.0 mm. The length of the wiring 107 is 1.7 mm. The wiring width of each of the wiring 104, the wiring 105, the wiring 106, and the wiring 107 is 0.35 mm. The characteristic impedances of the wiring 106 and the wiring 107 are 75 Ω. The printed wiring board 101 does not have a conductor except for a portion in contact with the wiring 104, the wiring 105, and the signal terminal 103a, and a portion in contact with the ground terminal 103b within a range of a concentric circle having a radius of 3 mm centered on the signal terminal 103a of the mounted coaxial connector 103. In the range of the concentric circles, the region where the conductor is not present is filled with an insulator.

In the present example, the first signal filter 110 is a ferrite bead. The impedance of the first signal filter 110 at 1 GHz is 400 Ω. The second signal filter 111 is a coil (inductor). The inductance of the second signal filter 111 is 10 μH. The capacitance of the capacitor 113 is 0.1 μF. The resistance value of the resistor 114 is 6.8 Ω. The impedance of the signal terminal 103a of the signal transmitting and receiving circuit 102 is 70 Ω. The sum of the impedance of the signal terminal 103a and the resistance value of the resistor 114 is 76.8 Ω, which generally matches the 75 Ω characteristic impedance of the wiring 106.

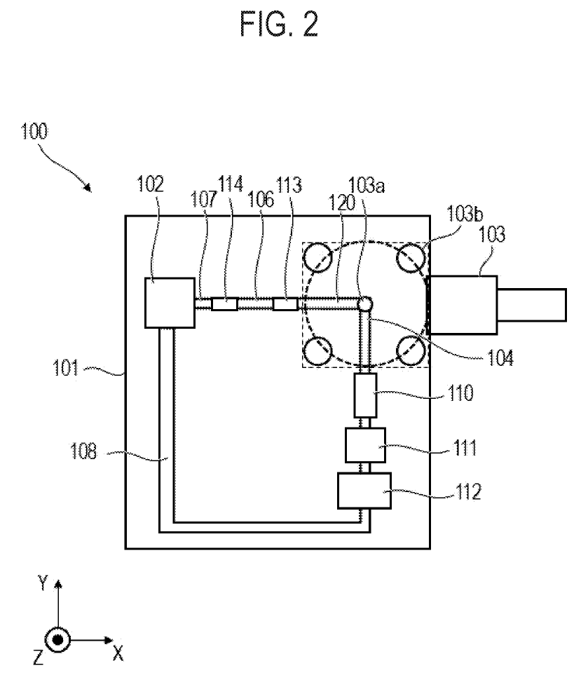

FIG. 2 is a top view illustrating Comparative Example of the circuit board 100 according to the first embodiment. The layer configuration of the printed wiring board 101, the positions of the components, and the constants in Comparative Example are the same as those in Example 1. Comparative Example differs from Example 1 in that wiring 105 is not provided, and the wiring 120 connected the signal terminal 103a of the coaxial connector 103 to one end of the capacitor 113. In Comparative Example, the wiring 104 serves as a stub for a high-frequency signal. The length of the wiring 120 is 3 mm. The width of the wiring 120 is 0.35 mm. The lengths of the wiring 104 and the wiring 106 are the same as those in Example 1.

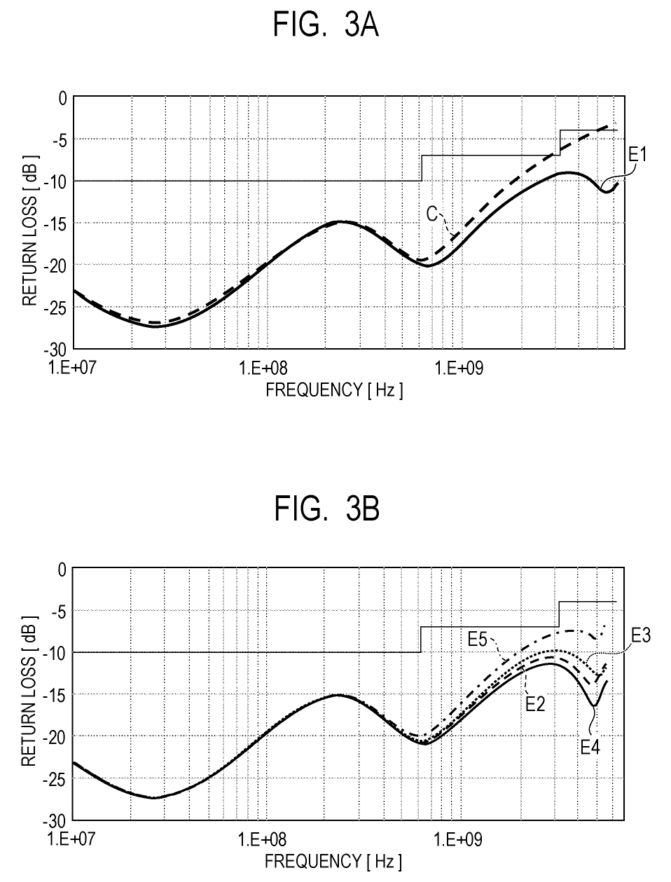

FIG. 3A is a diagram illustrating simulation results of the reflection characteristics of Example 1 and Comparative Example. The vertical axis indicates return loss (dB). The horizontal axis indicates frequency (Hz). The reflection characteristics are measured by the following method. First, when a coaxial cable is connected to the coaxial connector 103, a network analyzer (not illustrated) injected a sine wave signal into the circuit board 100 while sweeping the frequency. The injected sinusoidal signal is reflected off the circuit board 100 and returned to the network analyzer. The network analyzer measured the amount of reflection for each frequency. The ratio between the reflection amount and the injection amount is the return loss (dB). The smaller the value of the return loss is, the smaller the reflection amount is. In the simulation, the S-parameter (S11) is calculated for the signal terminal 103a of the coaxial connector 103, and the reflection characteristic (return loss) is obtained from this calculated value. As a simulator, HFSS, manufactured by ANSIS CORPORATION, is used.

In FIG. 3A, a broken line C indicates the return loss of Comparative Example. A solid line E1 indicates the return loss characteristic of Example 1. When the return loss at 6.25 GHz is compared, the return loss in Comparative Example having the stub is −3.2 dB. On the other hand, the return loss in Example 1, with no stub, is −10.6 dB. That is, the reflection in Example 1 is smaller than the reflection in Comparative Example. In Example 1, with no stub, the signal that had reached the first signal filter 110 is transmitted to the wiring 105 without returning to the signal terminal 103a. In contrast, in Comparative Example, the wiring 104 and the wiring 120 extended from the signal terminal 103a of the coaxial connector 103, respectively. Since the high-frequency signal transmitted to the wiring 104 is reflected by the first signal filter 110 and returned to the signal terminal 103a, the reflected wave is superimposed on the signal transmitted to the wiring 120. Therefore, the return loss in Comparative Example is larger than the return loss in Example 1.

In the CoaXPress (CXP) standard, a return loss allowable value is determined for each frequency. When the maximum signal transmission rate of the device-side circuit is 12.5 Gbps, the frequency range of 5 MHz to 625 MHz was −10 dB or less, the frequency range of 625 MHz to 3.2 GHz is −7 dB or less, and the frequency range of 3.2 GHz to 6.25 GHz is −4 dB or less.

### Example 2

FIG. 1C is a top view illustrating Example 2 of the circuit board 100. Since many parts are the same as those of Example 1, characteristic parts will be described. The shape of the wiring 105 in Example 2 is different from the shape of the wiring 105 in Example 1. Specifically, in the wiring 105, the width of one end connected to the first signal filter 110 is narrower than the width of the other end connected to one end (input terminal of the power supply circuit) of the capacitor 113. In Example 2, the width of one end of the wiring 105 is 0.175 mm. The width of the other end of the wiring 105 is 0.35 mm. The others are the same as in Example 1. A long-broken line E2 in FIG. 3B indicates the return loss characteristic in Example 2. The return loss at 6.25 GHz is −11.5 dB. According to Example 2, the return loss is smaller than that of Comparative Example.

### Example 3

FIG. 1D is a top view illustrating Example 3 of the circuit board 100. The shape of the wiring 104 in Example 3 is different from the shape of the wiring 104 in Example 1. Specifically, the width of one end of the wiring 104 connected to one end (input terminal of the power supply circuit) of the first signal filter 110 is narrower than the width of the other end of the wiring 104 connected to the signal terminal 103a. In Example 3, the width of one end of the wiring 104 is 0.175 mm. The width of the other end of the wiring 104 is 0.35 mm. The others are the same as in Example 1. A short-broken line E3 in FIG. 3B indicates the return loss characteristic in Example 3. The return loss at 6.25 GHz is −12.0 dB. According to Example 3, the return loss is smaller than that of Comparative Example.

### Example 4

FIG. 1E is a top view illustrating Example 4 of the circuit board 100. The shapes of the wiring 104 and the wiring 105 in Example 4 are different from the shapes of the wiring 104 and the wiring 105 in Example 1. Specifically, in the wiring 104, the width of one end connected to one end (input terminal of the power supply circuit) of the first signal filter 110 is narrower than the width of the other end connected to the signal terminal 103a. In Example 4, the width of one end of the wiring 104 is 0.175 mm. The width of the other end of the wiring 104 is 0.35 mm. In addition, in the wiring 105, the width of one end connected to the first signal filter 110 is narrower than the width of the other end connected to one end (input terminal of the power supply circuit) of the capacitor 113. In Example 4, the width of one end of the wiring 105 is 0.175 mm. The width of the other end of the wiring 105 is 0.35 mm. The lengths of the wiring 104 and the wiring 106 are the same as those in Example 1. A solid line E4 in FIG. 3B indicates the return loss characteristic in Example 4. The return loss at 6.25 GHz is −13.8 dB. According to Example 4, the return loss is smaller than that of Comparative Example.

The relationship between the width of the wiring and the characteristic impedance of the wiring in the above-described Examples 1 to 4 will be described in detail based on Example 4. In the same wiring, the characteristic impedance of the narrow portion is higher than that of the wide portion. On the other hand, the land (not illustrated) for mounting the first signal filter 110 on the substrate has a width corresponding to the size of the component. Therefore, the width of the land is larger than the widths of the wiring 104 and the wiring 105 in many cases. In Examples 1 to 4, the width of the land is 1.0 mm. Therefore, the impedance at the land become lower than the characteristic impedance of the wiring 104 and the wiring 105, and the impedance mismatch between the wiring 104 and the wiring 105 occurred. On the other hand, in Example 4, in order to correct the decrease in impedance at the land, the width of one end connected to the land in each of the wiring 104 and the wiring 105 is made narrower than the width of the other end connected to the first signal filter 110. As a result, the return loss in Example 4 become smaller than the return loss in Example 1.

### Example 5

FIG. 1F is a top view illustrating Example 5 of the circuit board 100. Here, the wiring 105 branches from the wiring 104 and is connected to one end (a first terminal of the signal circuit) of the capacitor 113. The distance between the position where the wiring 105 branches from the wiring 104 and the signal terminal 103a of the wiring 104 is 2.3 mm. The lengths of the wiring 104 and the wiring 106 are the same as those in Example 1.

A dashed-dotted line E5 in FIG. 3B indicates the return loss characteristic in Example 5. The return loss at 6.25 GHz is −6.7 dB. According to Example 5, the return loss is smaller than that of Comparative Example. When the wiring 105 branches from the wiring 104, a stub is generated. However, when the stub is short, the generated reflection is small. In Example 5, a distance d2 between a position where the wiring 105 branches from the wiring 104 and one end of the first signal filter 110 of the wiring 104 is 1.2 mm. According to the CXP standard, a signal is transmitted at a maximum rate of 12.5 Gbps. When the transmission speed is 12.5 Gbps, the distance between the position at which the wiring 105 branches from the wiring 104 and the first signal filter 110 is preferably 2.0 mm or less.

### Second Embodiment

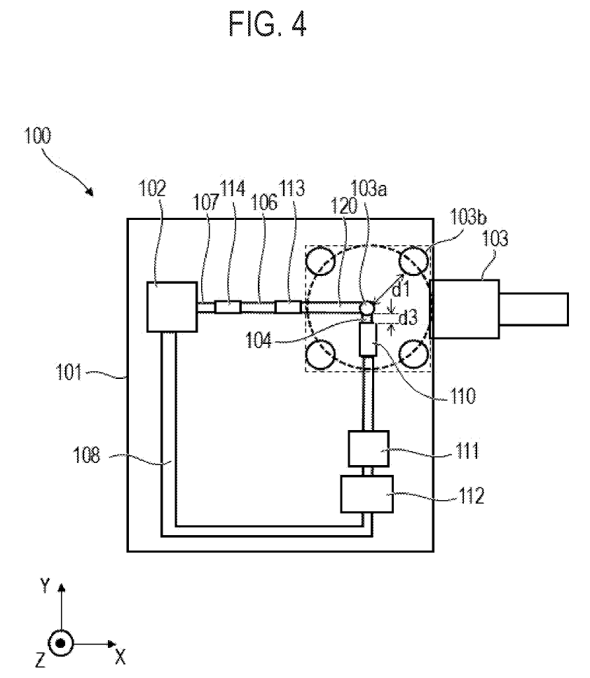

FIG. 4 is a top view illustrating the circuit board 100 according to a second embodiment. In the following description, the differences between the second embodiment and the first embodiment will mainly be described.

In the second embodiment, the wiring 105 illustrated in the first embodiment is not provided. In the second embodiment, a wiring 120 (second wiring) connecting the signal terminal 103a and the first terminal of the capacitor 113 is provided. The wiring 104 and the wiring 120 extend from the signal terminal 103a.

In the second embodiment, in a plan view of the printed wiring board 101, one terminal (input terminal of the signal circuit) of the first signal filter 110 is provided at a position closer to the signal terminal 103a (main terminal) than the ground terminal 103b (sub-terminal) of the coaxial connector 103. The first signal filter 110 overlaps the coaxial connector 103 in the plan view of the printed wiring board 101.

The length of the wiring 104 corresponds to a distance d3 between the signal terminal 103a and the first signal filter 110. The length of the wiring 104 is shorter than the length of the wiring 120. The length of the wiring 104 is preferably shorter than the distance d1 between the signal terminal 103a and the ground terminal 103b, and 0.7 times or less the distance d1.

### Example

Next, an example of the circuit board 100 illustrated in FIG. 4 will be described. The configuration of the circuit board 100 in the present example is common to many parts of the configuration of the circuit board 100 in Comparative Example of the first embodiment illustrated in FIG. 2. Therefore, the circuit board 100 illustrated in FIG. 2 is used as Comparative Example with respect to the present example.

The length of the wiring 104 in the present example, is 0.5 mm. The length of the wiring 120 is 3 mm.

Further, the size of the first signal filter 110 in the present example is smaller than that in Comparative Example. The sizes of the first signal filter 110 in the present example are 1.0 mm in length and 0.5 mm in width in the plan view. On the other hand, the size of the first signal filter 110 in Comparative Example is 1.6 mm in length and 0.8 mm in width. The sizes of the parts other than the wiring 104 and the first signal filter 110 are the same as those of Example 1 and Comparative Example of the first embodiment. In the present example, since the size of the first signal filter 110 is smaller than that of Comparative Example, the possibility of a short circuit between the first signal filter 110 and the ground terminal 103b is also low. Therefore, the first signal filter 110 can be disposed within a range surrounded by the four ground terminals 103b of the coaxial connector 103. Further, since the first signal filter 110 can be disposed close to the signal terminal 103a, the wiring 104, being a stub, can be shortened.

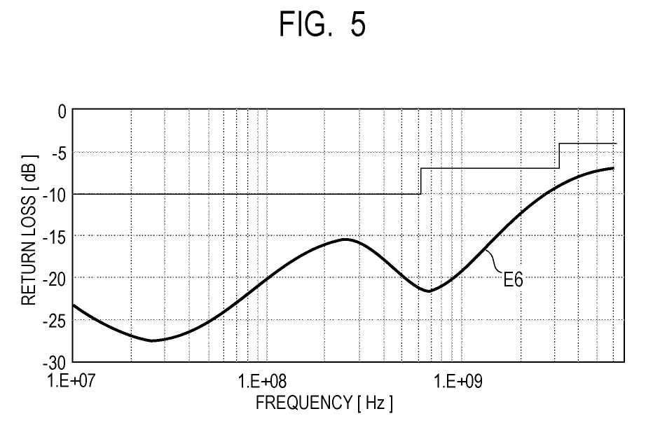

FIG. 5 is a diagram illustrating simulation results of reflection characteristics in Example and Comparative Example of the circuit board 100 according to the second embodiment. A solid line E6 indicates the return loss characteristic of the present example. The return loss at 6.25 GHz is −7.0 dB. The return loss is smaller than that of Comparative Example illustrated in FIG. 3A. In the present example, the length of the wiring 104, being a stub, is preferably 2.5 mm or less when the transmission speed is 12.5 Gbps.

### Modified Embodiments

The present disclosure is not limited to the above-described embodiments, and various modifications are possible. For example, an example in which a part of the configuration of any of the embodiments is added to another embodiment, or an example in which a part of the configuration of another embodiment is replaced with another embodiment, is also an embodiment of the present disclosure. In addition, the effects described in the embodiments merely enumerate the most preferable effects generated from the present disclosure, and the effects according to the present disclosure are not limited to those described in the embodiments.

Although the structure of the circuit board has been described in the above embodiment, the embodiment of the present disclosure is not limited to the circuit board. Electronic equipment, including a housing and a circuit board disposed inside the housing, is also an embodiment of the present disclosure. The electronic equipment may further include an imaging module that is disposed inside the housing and outputs the generated video signal to the signal transmitting and receiving circuit. The signal transmitting and receiving circuit outputs a video signal from the imaging module to the external device via the signal circuit and the connector. Such electronic equipment is also an embodiment of the present disclosure. Examples of electronic equipment include a CMOS camera that conforms to the CXP standard and transmits a video signal, a power supply, a control signal, and the like through a single coaxial cable.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

According to the present disclosure, a circuit board capable of reducing signal degradation is provided.

This application claims the benefit of Japanese Patent Application No. 2024-213119, filed on December 6, 2024, which is hereby incorporated by reference herein in its entirety.

What is claimed is:

1. A circuit board comprising:
a wiring board;
a connector that is mounted on the wiring board and has a main terminal and a sub-terminal;
a power supply circuit that is mounted on the wiring board and has an input terminal and an output terminal;
a signal circuit that is mounted on the wiring board and has a first terminal and a second terminal; and
a signal transmitting and receiving circuit that is mounted on the wiring board and has a power supply terminal and a signal terminal,
wherein the main terminal and the sub-terminal pass through the wiring board,
wherein the wiring board includes:
a first wiring that connects the main terminal and the input terminal;
a second wiring that connects the input terminal and the first terminal without passing through the main terminal;
a third wiring that connects the output terminal and the power supply terminal; and
a fourth wiring that connects the second terminal and the signal terminal, and
wherein the second wiring passes between the main terminal and the sub-terminal.

2. The circuit board according to claim 1,
wherein the connector further includes a connectable portion to which the coaxial cable is connected,
wherein the sub-terminal is a ground terminal,
wherein the wiring board has a first mounting surface and a second mounting surface opposite to the first mounting surface,
wherein the signal circuit and the signal transmitting and receiving circuit are mounted on the first mounting surface,
wherein the first terminal and the second terminal are soldered to the first mounting surface,
wherein the connectable portion is disposed on the second mounting surface side, and
wherein the second wiring is provided on the first mounting surface.

3. The circuit board according to claim 1, wherein the width of one end of the first wiring connected to the input terminal is narrower than the width of the other end connected to the main terminal.

4. The circuit board according to claim 1, wherein the width of one end of the second wiring connected to the input terminal is narrower than the width of the other end connected to the first terminal.

5. The circuit board according to claim 1,
wherein the connector further includes another sub-terminal,
wherein the second wiring does not pass between the another sub-terminal and the main terminal.

6. The circuit board according to claim 1, wherein the second wiring branches from the first wiring and is connected to the first terminal.

7. The circuit board according to claim 6, wherein the second wiring branches from the first wiring at a position closer to the input terminal than the main terminal.

8. The circuit board according to claim 1,
wherein the power supply circuit includes:
a first signal filter that is connected to the first wiring and has a first cutoff frequency;
a second signal filter that is connected to the first signal filter and has a second cutoff frequency lower than the first cutoff frequency; and
a converter that is connected to the second signal filter and outputs a power supply voltage to the power supply terminal of the signal transmitting and receiving circuit.

9. The circuit board according to claim 1,
wherein the signal circuit includes:
a capacitor that is connected to the first wiring; and
a resistor that is connected to the capacitor and the signal terminal of the signal transmitting and receiving circuit.

10. The circuit board according to claim 9, wherein the sum of an input impedance of the signal transmitting and receiving circuit and a resistance value of the resistor matches a characteristic impedance of the third wiring.

11. The circuit board according to claim 1, wherein in a plan view of the wiring board, a distance between the main terminal and the input terminal is longer than a distance between the main terminal and the sub-terminal.

12. The circuit board according to claim 1, wherein the length of the first wiring is shorter than the length of the second wiring.

13. A circuit board comprising:
a wiring board;
a connector that is mounted on the wiring board and has a main terminal and a sub-terminal;
a power supply circuit that is mounted on the wiring board and has an input terminal and an output terminal;
a signal circuit that is mounted on the wiring board and has a first terminal and a second terminal; and
a signal transmitting and receiving circuit that is mounted on the wiring board and has a power supply terminal and a signal terminal,
wherein the main terminal and the sub-terminal pass through the wiring board,
wherein the wiring board includes:
a first wiring that connects the main terminal and the input terminal;
a second wiring that connects the main terminal and the first terminal;
a third wiring that connects the output terminal and the power supply terminal; and
a fourth wiring that connects the second terminal and the signal terminal, and
wherein, in a plan view of the wiring board, the input terminal is positioned closer to the main terminal than the sub-terminal.

14. The circuit board according to claim 13, wherein the length of the first wiring is 0.7 times or less than the distance between the main terminal and the sub-terminal.

15. The circuit board according to claim 13, wherein the length of the first wiring is shorter than the length of the second wiring.

16. The circuit board according to claim 13,
wherein the connector further includes a connectable portion to which the coaxial cable is connected,
wherein the sub-terminal is a ground terminal,
wherein the wiring board has a first mounting surface and a second mounting surface opposite to the first mounting surface,
wherein the signal circuit and the signal transmitting and receiving circuit are mounted on the first mounting surface,
wherein the first terminal and the second terminal are soldered to the first mounting surface,
wherein the connectable portion is disposed on the second mounting surface side, and
wherein the second wiring is provided on the first mounting surface.

17. The circuit board according to claim 13,
wherein the power supply circuit includes:
a first signal filter that is connected to the first wiring and has a first cutoff frequency;
a second signal filter that is connected to the first signal filter and has a second cutoff frequency lower than the first cutoff frequency; and
a converter that is connected to the second signal filter and outputs a power supply voltage to the power supply terminal of the signal transmitting and receiving circuit,
wherein the first signal filter overlaps the connector in a plan view of the wiring board.

18. The circuit board according to claim 13, wherein the width of one end of the first wiring connected to the input terminal is narrower than the width of the other end connected to the main terminal.

19. An electronic equipment comprising:
a housing; and
the circuit board according to claim 1, disposed inside the housing.

20. The electronic equipment according to claim 19, further comprising:
an imaging module that is disposed inside the housing and outputs a generated video signal to the signal transmitting and receiving circuit,
wherein the signal transmitting and receiving circuit outputs the video signal to an external device via the signal circuit and the connector.
